(19) United States
(12) Patent Application Publication
(10) Pub. No.: US 2026/0036609 A1
(43) Pub. Date: Feb. 5, 2026

(54) SIGNAL MEASURING METHOD, COMPUTER READABLE RECORDING MEDIUM, AND ELECTRONIC APPARATUS

(71) Applicant: Novatek Microelectronics Corp., Hsinchu (TW)

(72) Inventor: Zhen-Hong Hung, New Taipei City (TW)

(73) Assignee: Novatek Microelectronics Corp., Hsinchu (TW)

(21) Appl. No.: 19/006,232

(22) Filed: Dec. 31, 2024

(30) Foreign Application Priority Data
Aug. 5, 2024 (TW) 113129133

(51) Int. Cl. G01R 19/25

(52) U.S. Cl. CPC G01R 19/2506

(57) ABSTRACT

A signal measuring method is adapted to measure a low voltage differential signal. The signal measuring method includes: receiving the low voltage differential signal via a low voltage differential signal receiver; comparing the low voltage differential signal with a reference voltage, and accumulating comparison results over one or more frame periods to generate an accumulation result; comparing the accumulation result with reference data to obtain statistical characteristics of the low voltage differential signal; and generating an eye diagram corresponding to the low voltage differential signal according to the statistical characteristics of the low voltage differential signal.

### CROSS-REFERENCE TO RELATED APPLICATION

This application claims the priority benefit of Taiwan application serial no. 113129133, filed on Aug. 5, 2024. The entirety of the above-mentioned patent application is hereby incorporated by reference herein and made a part of this specification.

### BACKGROUND

### Technical Field

The disclosure relates to a signal measuring method, a computer readable recording medium, and an electronic apparatus, and in particular to a low voltage differential signaling (LVDS) measuring method, a computer readable recording medium, and an electronic apparatus.

### Description of Related Art

LVDS is a low voltage differential signal transmitted in parallel through multiple lanes. LVDS video interface is widely used in display systems. For example, a display driver chip may use the LVDS video interface to receive display signals transmitted by the front-end circuit thereof, and use the received data to output signals and drive the display panel to display images. In addition, the LVDS video interface may also be used in vehicle systems to provide reliable signal transmit interface for vehicle applications. Since the LVDS video interface uses a low voltage and low current driving method, low-noise and low-power signal transmission functions can be achieved.

In practical applications, it is necessary to measure all lanes of LVDS signals to verify whether the preset specifications are met to transmit data stably. However, the conventional technology uses special detection tools to analyze and measure LVDS signals, and the chip cannot adaptively measure the LVDS signals to learn the signal characteristics.

### SUMMARY

The disclosure provides a signal measuring method, a computer readable recording medium, and an electronic apparatus that can adaptively measure LVDS (low voltage differential signaling) signals to learn signal characteristics, thereby the chip parameters may be further adjusted.

The signal measuring method of the disclosure is adapted to measure an LVDS signal. The signal measuring method includes: receiving the LVDS signal via an LVDS signal receiver; comparing the LVDS signal with the reference voltage, and accumulating the comparison results over one or more frame periods to generate an accumulation result; comparing the accumulation result with reference data to obtain statistical characteristics of the LVDS signal; and generating an eye diagram corresponding to the LVDS signal according to the statistical characteristics of the LVDS signal.

The computer readable recording medium according to an embodiment of the disclosure includes a computer program so that a computer performs the signal measuring method after performing the computer program.

The electronic apparatus according to an embodiment of the disclosure includes a processor and a storage device. The storage device stores the computer program so that the processor performs the signal measuring method after performing the computer program.

Based on the above, in order to make the above features and advantages of the disclosure more comprehensible, embodiments are given below and described in detail with reference to the accompanying drawings.

### BRIEF DESCRIPTION OF THE DRAWINGS

FIG. 1 is a schematic block diagram of an LVDS (low voltage differential signaling) signal measurement system according to an embodiment of the disclosure.

FIG. 2 is an internal schematic diagram of an LVDS signal measurement device and a driver circuit according to an embodiment of FIG. 1.

FIG. 3 is an internal schematic diagram of an LVDS receiver according to an embodiment of FIG. 2.

FIG. 4 is an internal schematic diagram of the LVDS receiver according to another embodiment of the disclosure.

FIG. 5 is a schematic overview diagram of a sense amplifier circuit according to an embodiment of the disclosure.

FIG. 6 is a schematic circuit diagram of the sense amplifier circuit and a D-type flip-flop according to an embodiment of FIG. 5.

FIG. 7 is a schematic block diagram of a digital statistics unit according to an embodiment of the disclosure.

FIG. 8 is a schematic block diagram of the digital statistics unit according to another embodiment of the disclosure.

FIG. 9 is a schematic block diagram of the LVDS signal measurement device according to another embodiment of the disclosure.

FIG. 10 is a step flow chart of a signal measuring method according to an embodiment of the disclosure.

FIG. 11 is a step flow chart of the signal measuring method according to another embodiment of the disclosure.

FIG. 12A and FIG. 12B are respectively schematic overview diagrams of statistical characteristic distribution and recovered eye diagram of LVDS signals.

### DESCRIPTION OF THE EMBODIMENTS

Each embodiment is provided below to illustrate the disclosure in detail, but the disclosure is not limited to the provided embodiments, and the provided embodiments may be combined in an appropriate manner. The terms “coupling/coupled” or “connecting/connected” used in the description of this application (including the claims) may refer to any direct or indirect connection method. For example, “a first device is coupled to a second device” should be interpreted as “the first device is directly connected to the second device” or “the first device is indirectly connected to the second device through other devices or connections.” In addition, the term “signal” may refer to current, voltage, charge, temperature, data, electromagnetic waves, or any one or more signals.

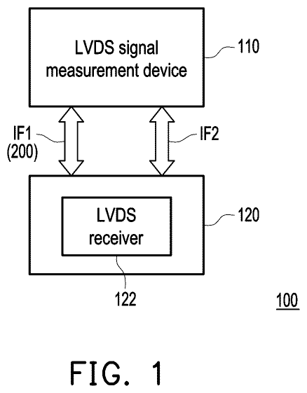

FIG. 1 is a schematic block diagram of an LVDS (low voltage differential signaling) signal measurement system according to an embodiment of the disclosure. Referring to FIG. 1, an LVDS signal measurement system 100 includes an LVDS signal measurement device 110 and a driver circuit 120. The driver circuit 120 includes an LVDS receiver 122. In this embodiment, the driver circuit 120 includes but is not limited to a display driver integrated circuit (DDIC), a touch and display driver integration (TDDI) chip, or a timing controller chip.

During normal operation, the LVDS receiver 122 of the driver circuit 120 may receive the LVDS signal transmitted by the upper-level circuit through the LVDS video interface. In addition, the driver circuit 120 may perform signal processing on the LVDS signal, and then transmit the processed signal to a next-level circuit to drive the next-level circuit to perform the corresponding function.

In this embodiment, the LVDS signal measurement device 110 is used to perform a signal measuring method on the driver circuit 120 to generate an eye diagram corresponding to an LVDS signal 200. Through the eye diagram information, the characteristics of the LVDS signal 200 may be further understood, thereby the system design is optimized, and the signal quality is improved. During signal measurement period, the driver circuit 120 serves as the circuit to be tested, and the LVDS signal 200 serves as the test signal. The LVDS signal measurement device 110 may transmit the LVDS signal 200 to the driver circuit 120 through an LVDS video interface IF1, and may transmit control commands to the driver circuit 120 through a transmit interface IF2 to control signal measurement.

For example, the LVDS signal measurement device 110 may output the LVDS signal 200 to the LVDS receiver 122, and cooperate with the LVDS receiver 122 to perform bit error testing on the LVDS signal 200, thereby the eye diagram of the LVDS signal 200 is restored according to the statistical characteristics of the signal, such as the bit error rate (BER). In this embodiment, the statistical characteristics are, for example, characteristics such as the bit error rate, occurrence rate of bit 1 (the signal being higher than the reference voltage), or occurrence rate of bit 0 (the signal being lower than the reference voltage). After processing the statistical characteristics, the eye diagram may be generated. According to the eye diagram analysis, signal characteristics may be further understood. Specifically, the eye diagram is formed by a series of overlapping pulse wave responses, and each waveform represents a signal sample at a different time point. When a continuous digital signal is interfered with or distorted during transmission, the shape of the signal waveform is changed. By combining the waveforms, deforming phenomena of the signal may be seen. The main purpose of the eye diagram is to evaluate the signal quality of the system during data transmission and to detect problems in data transmission. For example, eye diagrams may be used to detect issues such as signal distortion, timing offset, and spurious interference. By analyzing the eye diagram, the signal characteristics may be further understood, thereby the system design is optimized, and the signal quality is improved.

The LVDS signal measurement device 110 may be used to set the measurement environment, such as a test pattern or scanning position, and may keep the driver circuit 120 under normal operation for signal measurement. In addition, the LVDS signal measurement device 110 may also ensure that each signal line may be measured through switching signal lanes.

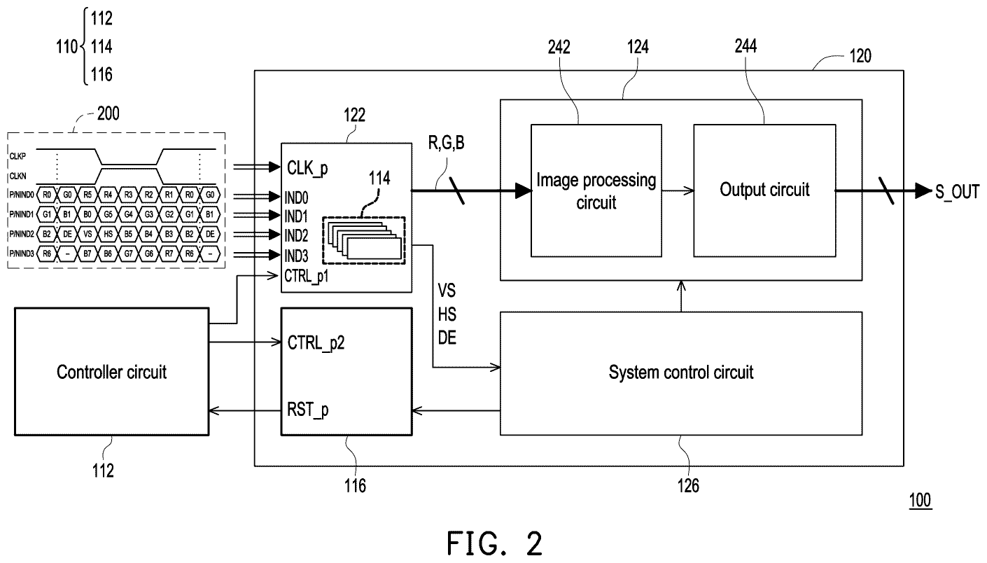

FIG. 2 shows an internal schematic diagram of the LVDS signal measurement device 110 and the driver circuit 120 according to the embodiment of FIG. 1. Referring to FIG. 2, the LVDS signal measurement device 110 includes a controller circuit 112, an analog control unit 114, and a digital statistics unit 116. The driver circuit 120 includes the LVDS receiver 122, a data processing circuit 124, and a system control circuit 126.

The LVDS signal 200 includes a set of clock signals CLKP, CLKN and four sets of data signals P/NIND0, P/NIND1, P/NIND2, P/NIND3. The LVDS receiver 122 receives the clock signals CLKP, CLKN and the data signals P/NIND0, P/NIND1, P/NIND2, P/NIND3 through pins CLK_p, IND0, IND1, IND2, and IND3 respectively. In this embodiment, the LVDS signal 200 is, for example, an 8-bit signal, and the signal format thereof complies with the VESA interface standard, but the disclosure is not limited thereto. In another embodiment, the LVDS signal 200 may also be in a signal format complying with the JEIDA interface standard. The difference between the VESA interface standard and the JEIDA interface standard lies in the different positions of the bit numbers of the three colors R, G, B. The disclosure does not limit the bit number and signal format of the LVDS signal 200.

The LVDS receiver 122 transmits image data of the three colors R, G, B to the data processing circuit 124. The data processing circuit 124 includes an image processing circuit 242 and an output circuit 244. The image processing circuit 242 is used to perform image processing operations on the image data R, G, B. The output control circuit 244 generates an output signal S_OUT according to the image processing result to a next-level circuit. In an embodiment of the driver circuit 120 being the DDIC or TDDI chip, the output signal S_OUT is, for example, a source drive signal. Alternatively, in an embodiment of the driver circuit 120 being a timing controller chip, the output signal S_OUT is, for example, other interface signals. The disclosure does not limit the type of the output signal S_OUT.

The LVDS receiver 122 transmits control signals HS, VS, DE to the system control circuit 126. The system control circuit 126 controls the overall operation sequence of the data processing circuit 124 according to the control signals HS, VS, DE.

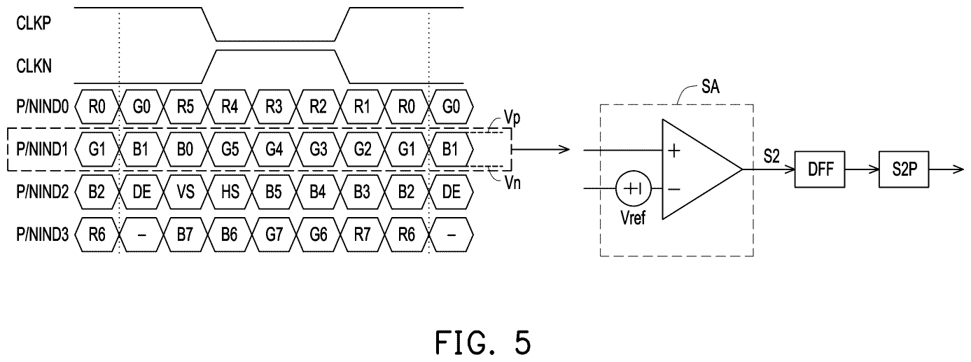

On the other hand, the analog control unit 114 is used to provide a reference voltage Vref to a sense amplifier circuit SA (as shown in FIG. 5) in the LVDS receiver 122 for comparison with the LVDS signal 200. The analog control unit 114 may also be used to adjust the magnitude of the reference voltage Vref to completely scan the eye diagram of a preset voltage range. The digital statistics unit 116 accumulates comparison results over one or more frame periods, and calculates the accumulation result and the reference result to provide the calculation result to the controller circuit 112 through a pin RST_p. The reference result may be a preset standard result or an accumulation result of the previous measurement. The controller circuit 112 determines whether a bit error occurs and what the bit error rate is according to the calculation result and adjusts chip parameters accordingly, such as adjusting the current value of the driving current of the LVDS receiver 122.

In the embodiment of FIG. 2, the LVDS signal measurement device 110 implements signal measurement through, for example, a hardware circuit. The LVDS signal measurement device 110 includes hardware circuits such as the controller circuit 112, the analog control unit 114, and the digital statistics unit 116. The analog control unit 114 and the digital statistics unit 116 are disposed inside the driver circuit 120, and the controller circuit 112 is disposed outside the driver circuit 120. That is to say, part or all of the hardware circuit of the LVDS signal measurement device 110 may be disposed inside the driver circuit 120 to perform the signal measuring method. The disclosure does not limit which hardware circuits are disposed inside the driver circuit 120. In the embodiment of FIG. 2, the controller circuit 112 transmits control commands to the analog control unit 114 and the digital statistics unit 116 through pins CTRL_p1, CTRL_p2 respectively to control the two circuit units to perform the signal measuring method.

The hardware structure of the controller circuit 112, the analog control unit 114, and the digital statistics unit 116 may be designed through a hardware description language (HDL) or any other digital circuit design method well known to persons having ordinary knowledge in the art, and may be hardware circuit implemented by manners of Field Programmable Gate Array (FPGA), Complex Programmable Logic Device (CPLD), or Application-specific Integrated Circuit (ASIC). Alternatively, the controller circuit 112 may be a processor with computing capabilities.

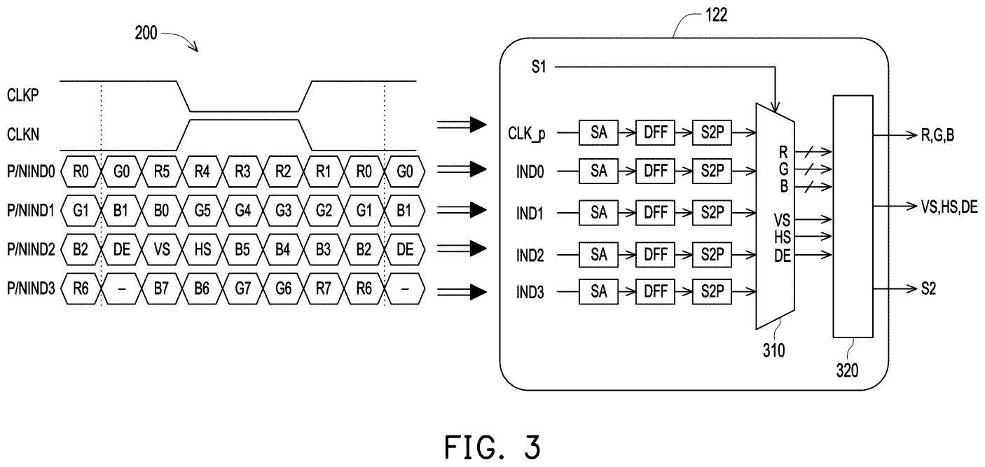

FIG. 3 is an internal schematic diagram of the LVDS receiver 122 according to an embodiment of FIG. 2. Referring to FIG. 3, the LVDS receiver 122 receives the clock signals CLKP, CLKN and the data signals P/NIND0, P/NIND1, P/NIND2, P/NIND3 through the pins CLK_p, IND0, IND1, IND2, IND3 respectively. Since the clock signals CLKP, CLKN and the data signal P/NIND2 include information controlling the overall operation of the LVDS receiver 122, in order to ensure that the LVDS receiver 122 may perform signal measurement under normal operation, the LVDS signal measurement device 110 first measures the data signals P/NIND0, P/NIND1, P/NIND3 (first data signals) in a first stage. The corresponding sense amplifier circuit SA compares the data signals P/NIND0, P/NIND1, P/NIND3 with the reference voltage, and outputs the comparison results to a corresponding D-type flip-flop DFF and a series-to-parallel circuit S2P.

The LVDS signal measurement device 110 switches the output of a multiplexer circuit 310 through a switch signal S1, so that the comparison results of the data signals P/NIND0, P/NIND1, P/NIND3 in the first stage are stored in a storage circuit 320. Then, the storage circuit 320 outputs a comparison result S2 to the digital statistics unit 116, and then the digital statistics unit 116 accumulates the comparison results S2 over one or more frame periods to generate an accumulation result. The storage circuit 320 is, for example, a first input first output storage, but the disclosure does not limit the type of the storage circuit 320.

Then, the LVDS signal measurement device 110 measures the clock signals CLKP, CLKN and the data signal P/NIND2 (a second data signal) in a second stage and switches the multiplexer circuit 310 through the switch signal S1, so that the multiplexer circuit 310 outputs the comparison results of the clock signals CLKP, CLKN and the data signal P/NIND2 to the storage circuit 320 in the second stage. That is to say, the LVDS signal measurement device 110 outputs the switch signal S1 to the LVDS receiver 122, so that the LVDS receiver 122 may output the comparison results corresponding to the data signals P/NIND0, P/NIND1, P/NIND3 and the comparison results corresponding to the clock signals CLKP, CLKN and the data signal P/NIND2 at different stages.

Therefore, in the embodiment of FIG. 3, the LVDS signal measurement device 110 switches the signal lanes by the switch signal S1 to ensure that each signal line of the LVDS receiver 122 may be measured under normal operation.

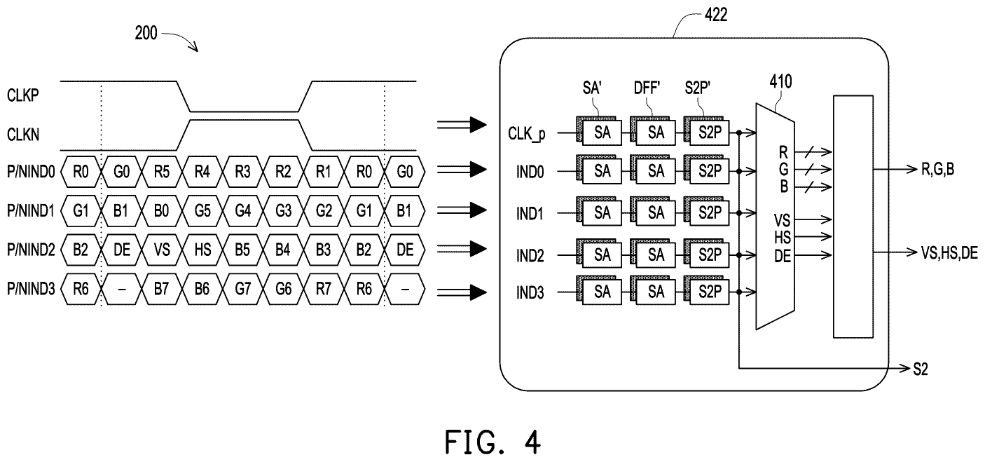

FIG. 4 is an internal schematic diagram of the LVDS receiver according to another embodiment of the disclosure. Please refer to FIG. 4. In the embodiment of FIG. 4, a new set of sense amplifier circuit SA′, D-type flip-flop DFF′, and series-to-parallel circuit S2P′ may be added to an LVDS receiver 422 corresponding to the original sense amplifier circuit SA, the D-type flip-flop DFF, and the series-to-parallel circuit S2P. During signal measurement period, the LVDS signal measurement device 110 may measure the clock signals CLKP, CLKN and the data signals P/NIND0, P/NIND1, P/NIND2, P/NIND3 in the same measurement stage through controlling the sense amplifier circuit SA′ and the series-to-parallel circuit S2P′, and the comparison result S2 is directly output to the digital statistics unit 116 for accumulation by the series-to-parallel S2P′ without going through a multiplexer circuit 410.

In the embodiment of FIG. 4, by adding the new set of sense amplifier circuit SA′ and series-to-parallel circuit S2P′ in the LVDS receiver 422, it may also be ensured that each signal line of the LVDS receiver 422 may be measured under normal operation.

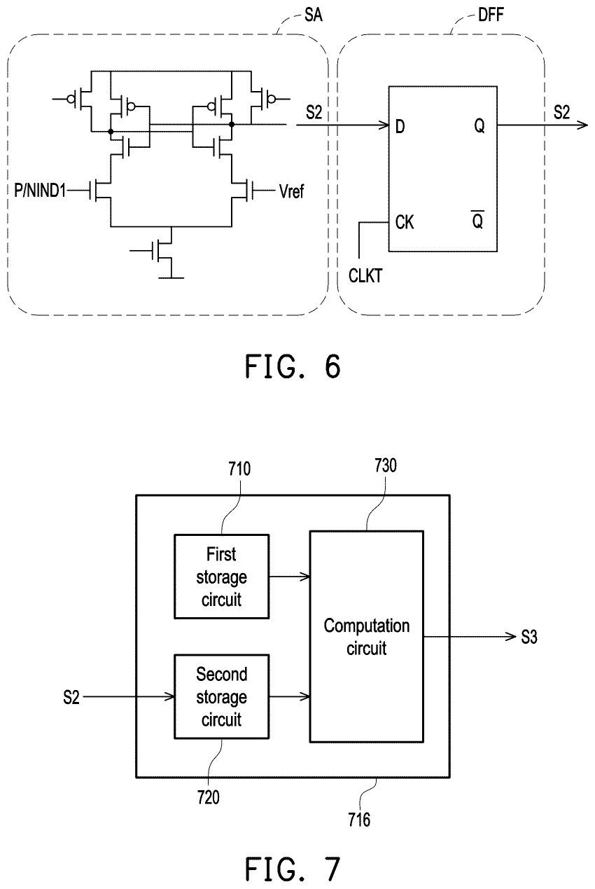

FIG. 5 is a schematic overview diagram of a sense amplifier circuit according to an embodiment of the disclosure. FIG. 6 is a schematic circuit diagram of the sense amplifier circuit and the D-type flip-flop according to an embodiment of FIG. 5. Please refer to FIG. 5 and FIG.

6. The sense amplifier circuit SA has a non-inverting terminal, an inverting terminal, and an output terminal. Taking the data signal P/NIND1 as an example, the non-inverting terminal of the sense amplifier circuit SA receives the data signal P/NIND1, and the inverting terminal of the sense amplifier circuit SA receives the reference voltage Vref. The sense amplifier circuit SA compares the data signal P/NIND1 and the reference voltage Vref, and outputs the comparison result S2 to the D-type flip-flop DFF at the output terminal thereof.

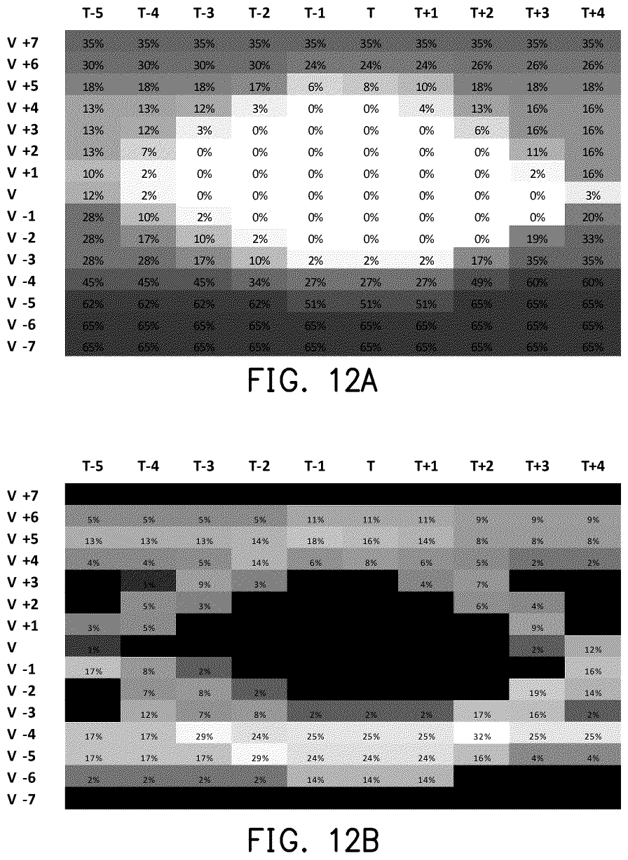

Specifically, the data signal P/NIND1 includes a first voltage Vp and a second voltage Vn, and the voltage difference is (Vp−Vn). The sense amplifier circuit SA compares the voltage difference (Vp−Vn) with the reference voltage Vref to generate the comparison result S2. For example, if (Vp−Vn)>Vref, the sense amplifier circuit SA outputs a bit value of 1, that is, the signal is higher than the reference voltage. On the contrary, if (Vp−Vn)≤Vref, the sense amplifier circuit SA outputs a bit value of 0, that is, the signal is lower than the reference voltage. Therefore, the comparison result S2 may be bit value 1 or 0. The analog control unit 114 may be used to adjust the voltage value of the reference voltage Vref to adjust reference coordinates of the eye diagram, such as the voltage range V+7 to V−7 in FIG. 12B. The digital statistics unit 116 may calculate the quantity of bit values 1 corresponding to the data signal P/NIND1 over one or more frame periods. In addition, a clock input terminal CK of the D-type flip-flop DFF is used to receive a tunable clock signal CLKT. Tuning the clock signal CLKT may adjust the reference coordinates of the eye diagram, such as the time range T−5 to T+4 in FIG. 12B.

FIG. 7 is a schematic block diagram of the digital statistics unit according to an embodiment of the disclosure. Referring to FIG. 7, a digital statistics unit 716 includes a first storage circuit 710, a second storage circuit 720, and a computation circuit 730. The first storage circuit 710 is used to store reference data. The second storage circuit 720 is used to accumulate and store the comparison results S2 over one or more frame periods. The computation circuit 730 is used to calculate the bit error status of the LVDS signal 200 under a certain amount of data, and provide a computation result S3 to the controller circuit 112. The controller circuit 112 determines whether a bit error occurs and what the bit error rate is according to the computation result S3, so as to adjust the chip parameters.

In this embodiment, the reference data stored in the first storage circuit 710 may be externally input or internally defined. The internal definition may be all bit values 0 or bit values 1. Alternatively, the internal definition may be specific picture data received by both the transmitting terminal and the receiving terminal. The disclosure does not limit the form of reference data. For example, before performing the measurement, the LVDS signal measurement device 110 may first set the driver circuit 120 in a normal operation state, then transmit the low voltage differential signal 200 to the LVDS receiver 122, and use the measurement result at this time as the reference data. The low voltage differential signal 200 includes fixed transmission data or static pictures. The fixed transmission data includes, for example, non-static picture data formed by pseudo random binary sequence (PRBS) or videos.

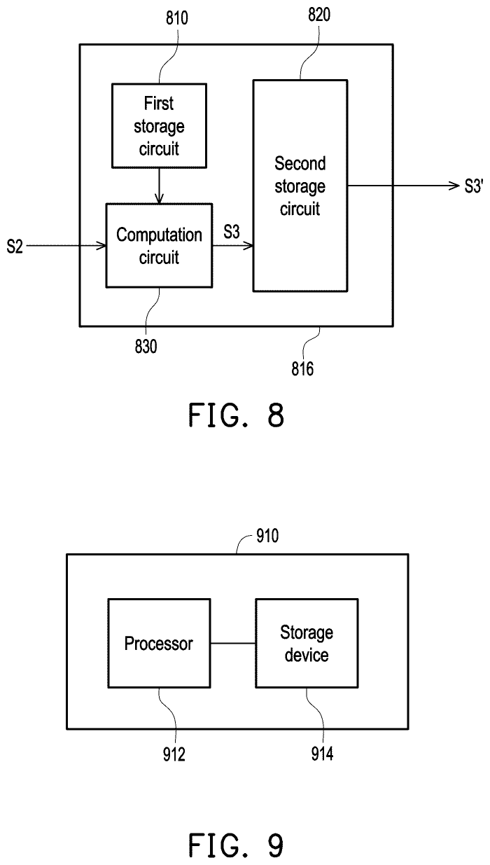

FIG. 8 is a schematic block diagram of the digital statistics unit according to another embodiment of the disclosure. Please refer to FIG. 8. In this embodiment, in a digital statistics unit 816, according to the reference data and the comparison result S2 stored in a first storage circuit 810, the bit error status of the LVDS signal 200 under a certain amount of data may calculate in real time by a computation circuit 830, and the calculation result S3 is stored in a second storage circuit 820. Then, the second storage circuit 820 provides a computation result S3′ of one or more frame periods to the controller circuit 112. The controller circuit 112 determines whether a bit error occurs and what the bit error rate is according to the computation result S3′, so as to adjust the chip parameters.

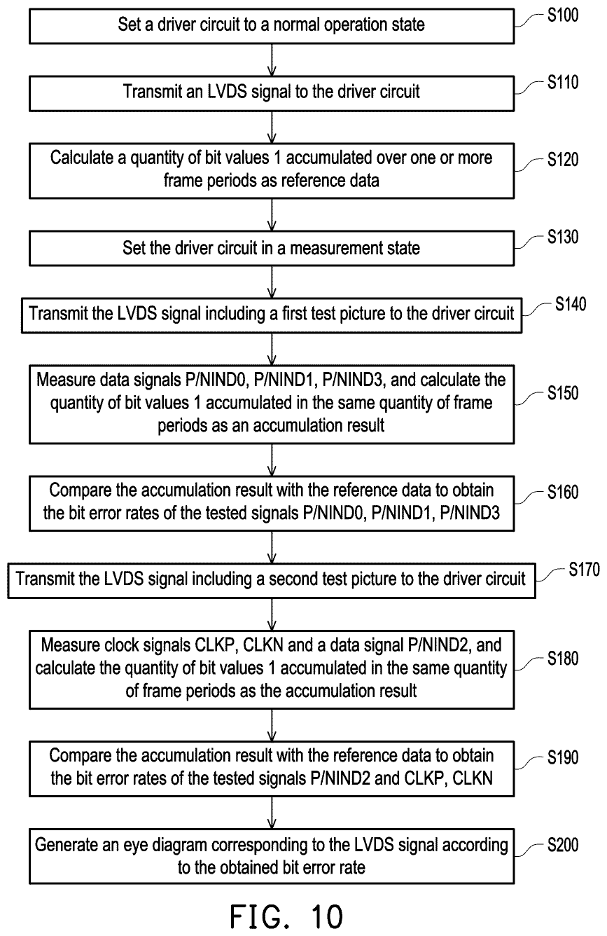

FIG. 9 is a schematic block diagram of the LVDS signal measurement device according to another embodiment of the disclosure. FIG. 10 is a step flow chart of a signal measuring method according to an embodiment of the disclosure. Please refer to FIG. 9 and FIG. 10. In the embodiments of FIG. 9 and FIG. 10, an LVDS signal measurement device 910 may implement signal measurement through software methods. Specifically, the LVDS signal measurement device 910 is, for example, an electronic apparatus including a processor 912 and a storage device 914. The LVDS signal measurement device 910 is, for example, a computer, and the storage device 914 is, for example, a computer readable recording medium including a computer program, so that the computer performs the signal measuring method in FIG. 10 after performing the computer program. The signal measuring method of this embodiment is adapted to system architecture with an LVDS receiver, which can measure and analyze the eye diagram of the LVDS signal to further understand the characteristics thereof, thereby the system design is optimized, and the signal quality is improved.

Specifically, in Step S100, the processor 912 sets the driver circuit 120 to a normal operation state. In Step S110, the processor 912 transmits the LVDS signal 200 including the static picture to the driver circuit 120, and is received by the LVDS receiver 122. In Step S120, the processor 912 calculates the quantity of bit values 1 accumulated over one or more frame periods as the reference data.

Next, in Step S130, the processor 912 sets the driver circuit 120 in a measurement state. In Step S140, the processor 912 transmits the LVDS signal 200 including a first test picture to the driver circuit 120, in which the first test picture may be the same as or different from the static picture. In Step S150, the processor 912 first measures the data signals P/NIND0, P/NIND1, P/NIND3, and calculates the quantity of bit values 1 accumulated in the same quantity of frame periods as in Step S120 as the accumulation result. In Step S160, the processor 912 compares the accumulation result with the reference data to obtain the bit error rates of the tested signals P/NIND0, P/NIND1, P/NIND3.

Next, in Step S170, the processor 912 transmits the LVDS signal 200 including a second test picture to the driver circuit 120, in which the second test picture may be the same as or different from the first test picture and the static picture. In Step S180, the processor 912 measures the clock signals CLKP, CLKN and the data signal P/NIND2, and calculates the quantity of bit values 1 accumulated in the same quantity of frame periods as in Step S120 as the accumulation result. In Step S190, the processor 912 compares the accumulation result with the reference data to obtain the bit error rates of the tested signals P/NIND2 and CLKP, CLKN.

In Step S200, the processor 912 generates an eye diagram corresponding to the LVDS signal 200 according to the obtained bit error rate and the reference eye diagram to further understand the signal characteristics and thereby adjust the chip parameters. In an embodiment, the processor 912 adjusts, for example, the current value of the driving current of the LVDS receiver 122 to optimize the system design and improve the signal quality.

In an embodiment, the processor 912 is, for example, a central processing unit (CPU), or other programmable general-purpose or special-purpose micro control unit (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), a field programmable gate array (FPGA), or other similar components or a combination of the above components.

In an embodiment, the storage device 914 is used to store various software, data, and various program codes required when the LVDS signal measurement device 910 is in operation. The storage device 914 is, for example, any type of fixed or removable random access memory (RAM), read-only memory (ROM), flash memory, hard disk drive (HDD), solid state drive (SSD), or similar components or a combination of the above components, used to store multiple modules or various applications executable by the processor 912. In an embodiment, the storage device 914 may further include a database.

In addition, sufficient teachings, suggestions, and implementation descriptions of the signal measuring method of this embodiment may be obtained from the description of the embodiments of FIG. 1 to FIG. 8, so details will not be repeated here.

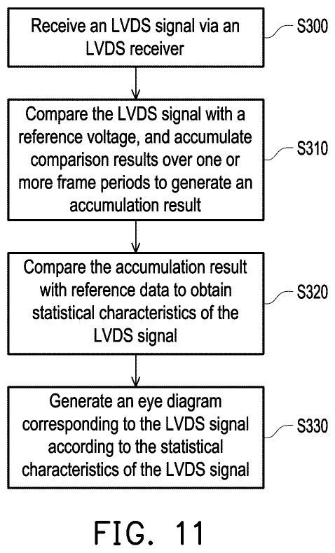

FIG. 11 is a step flow chart of the signal measuring method according to another embodiment of the disclosure. Please refer to FIG. 9 and FIG. 11. In Step S300, the LVDS signal 200 is received via the LVDS receiver 122. In Step S310, the processor 912 compares the LVDS signal 200 with the reference voltage Vref, and accumulates the comparison results over one or more frame periods to generate the accumulation result. In Step S320, the processor 912 compares the accumulation result with reference data to obtain the statistical characteristics of the LVDS signal 200, such as bit error rate. In Step S330, the processor 912 generates a recovered eye diagram corresponding to the LVDS signal 200 according to the bit error rate of the LVDS signal 200.

In addition, sufficient teachings, suggestions, and implementation descriptions of the signal measuring method of this embodiment may be obtained from the description of the embodiments of FIG. 1 to FIG. 10, so details will not be repeated here.

Each step of the signal measuring method in FIG. 10 and FIG. 11 may also be executed by the controller circuit 112, the analog control unit 114, and the digital statistics unit 116 in FIG. 2 to complete the signal measurement. In addition, the signal measuring method in FIG. 10 and FIG. 11 may be measured before the driver circuit 120 leaves the factory, or when the electronic apparatus equipped with the driver circuit 120 is turned on, so as to adaptively adjust the chip parameters.

FIG. 12A and FIG. 12B are respectively schematic overview diagrams of statistical characteristic distribution and recovered eye diagram of the LVDS signals. Please refer to FIG. 12A and FIG. 12B. Taking the measurement of the data signal P/NIND1 as an example, the LVDS signal measurement device 110 may obtain the statistical characteristics, such as bit error rate, shown in FIG. 12A at least through the signal measuring method in FIG. 10 and FIG. 11 and through normalization. The preset voltage range V+7 to V−7 and the preset time range T−5 to T+4 are the reference coordinates of the recovered eye diagram.

The LVDS signal measurement device 110 may obtain the bit error rate corresponding to the preset voltage range V+7 to V−7 corresponding to the recovered eye diagram by adjusting the voltage value of the reference voltage Vref. At the same time, the LVDS signal measurement device 110 may also obtain the bit error rate corresponding to the preset time range T−5 to T+4 of the eye diagram by adjusting the measurement timing. By adjusting the voltage parameters and time parameters, the LVDS signal measurement device 110 may completely scan the bit error rate corresponding to the range of one eye diagram.

The accumulated data obtained by the LVDS signal measurement device 110 is normalized corresponding to the quantity of test data to generate statistical characteristics, such as dividing the accumulated data by the quantity of test data. If the quantity of test data does not change within the scanning range of the LVDS signal measurement device 110, then the accumulated data obtained may represent the normalized statistical characteristics.

Then, the LVDS signal measurement device 110 generates the recovered eye diagram in FIG. 12B according to the statistical characteristic distribution and the reference coordinates in FIG. 12A to depict the eye diagram contour of the LVDS signal. The method of generating the recovered eye diagram in FIG. 12B may be, for example, to apply a high-pass filter to the statistical characteristic distribution in FIG. 12A.

In summary, in the embodiments of the disclosure, the LVDS signal measurement device may completely scan the signal bit error rate corresponding to the range of one eye diagram by adjusting the voltage value of the reference voltage and the signal measurement timing, thereby the recovered eye diagram of the LVDS signal is obtained. Through the eye diagram information, the characteristics of the LVDS signal may be further understood, thereby the system design is optimized, and the signal quality is improved. In addition, the LVDS signal measurement device may switch the signal lanes by the switch signal to ensure that each signal line of the LVDS receiver may be measured under normal operation. The LVDS signal measurement device may implement signal measurement through hardware circuits or software methods. The hardware circuit may be partially or completely installed in the chip circuit, so that the chip circuit may adaptively measure the LVDS signal to learn the signal characteristics, so that the chip parameters may be further adjusted. In the application example of the software method, a computer may be used to read the program in the recording medium and then execute the LVDS signal measuring method.

Although the disclosure has been disclosed above through embodiments, the embodiments are not intended to limit the disclosure. Persons with ordinary knowledge in the relevant technical field may make some changes and modifications without departing from the spirit and scope of the disclosure. Therefore, the protection scope of the disclosure shall be determined by the appended claims.

What is claimed is:

1. A signal measuring method to measure a low voltage differential signal, wherein the signal measuring method comprises:
receiving the low voltage differential signal via a low voltage differential signal receiver;
comparing the low voltage differential signal to a reference voltage, and accumulating comparison results over one or more frame periods to generate an accumulation result;
comparing the accumulation result with reference data to obtain statistical characteristics of the low voltage differential signal; and
generating an eye diagram corresponding to the low voltage differential signal according to the statistical characteristics of the low voltage differential signal.

2. The signal measuring method as claimed in claim 1, wherein the low voltage differential signal comprises at least one data signal, and in response to comparing the low voltage differential signal with the reference voltage, a voltage difference of the at least one data signal is compared with the reference voltage to generate the comparison results.

3. The signal measuring method as claimed in claim 1, wherein the low voltage differential signal comprises a plurality of first data signals, a second data signal, and a clock signal, and the second data signal and the clock signal are configured to control operation of the low voltage differential signal receiver.

4. The signal measuring method as claimed in claim 3, wherein the signal measuring method first measures the plurality of first data signals in a first stage, and then measures the second data signal and the clock signal in a second stage.

5. The signal measuring method as claimed in claim 4, further comprising:
outputting a switch signal to the low voltage differential signal receiver, so that the low voltage differential signal receiver outputs a comparison result corresponding to the plurality of first data signals and a comparison result corresponding to the second data signal and the clock signal at different stages.

6. The signal measuring method as claimed in claim 3, wherein the signal measuring method measures the plurality of first data signals, the second data signal, and the clock signal at same stage.

7. The signal measuring method as claimed in claim 3, further comprising:
transmitting the low voltage differential signal to the low voltage differential signal receiver, and using a measurement result as the reference data, wherein the low voltage differential signal comprises fixed transmission data or static pictures.

8. The signal measuring method as claimed in claim 1, further comprising:
adjusting a voltage value of the reference voltage to obtain the statistical characteristics of the low voltage differential signal in a preset voltage range.

9. A computer readable recording medium comprising a computer program so that a computer performs the signal measuring method as claimed in claim 1 after performing the computer program.

10. An electronic apparatus comprising a processor and a storage device, wherein the storage device stores a computer program so that the processor performs the signal measuring method as claimed in claim 1 after performing the computer program.
